(19) United States
(12) Patent Application Publication
(10) Pub. No.: US 2014/0184326 A1
(43) Pub. Date: Jul. 3, 2014

(54) POWER AMPLIFIER

(71) Applicant: FUJITSU LIMITED, Kawasaki-shi (JP)

(72) Inventor: Ken TAMANOI, Yokohama (JP)

(73) Assignee: FUJITSU LIMITED, Kawasaki-shi (JP)

(21) Appl. No.: 14/060,302

(22) Filed: Oct. 22, 2013

(30) Foreign Application Priority Data
Dec. 28, 2012 (JP) 2012-287753

(51) Int. Cl. H03F 1/02

(52) U.S. Cl. CPC H03F 1/02
USPC 330/127

(57) ABSTRACT

A power amplifier includes: an amplifier; a matching circuit, including a variable reactance magnetic device having a reactance which varies in accordance with a magnetic field, configured to match an output of the amplifier with a certain impedance; an amplitude detector configured to detect the amplitude of an input signal for the amplifier; and a magnetic-field control circuit configured to apply a magnetic field corresponding to the amplitude detected by the amplitude detector to the variable reactance magnetic device.

### CROSS-REFERENCE TO RELATED APPLICATION

This application is based upon and claims the benefit of priority of the prior Japanese Patent Application No. 2012-287753, filed on Dec. 28, 2012, the entire contents of which are incorporated herein by reference.

### FIELD

The embodiments discussed herein are related to power amplifiers.

### BACKGROUND

Because the power consumption of a power amplifier that amplifies a transmission signal is high in a wireless base station, it is important to improve the efficiency of the power amplifier in order to reduce power consumption in the wireless base station.

Related technologies are disclosed in, for example, Japanese Laid-open Patent Publications No. 61-20563, No. 2012-19515, No. 2008-206233, and No. 2006-180507.

Related technologies are also disclosed in, for example, Hossein Mashad Nemati, et al., “Design of Highly Efficient Load Modulation Transmitter for Wideband Cellular Applications” IEEE Trans. Microwave Theory Tech., vol. 58, no. 11, pp. 2820-2828, November 2010; Mohamed Gamal El Din, et al., “Load modulation for Efficiency Enhancement of Inverse Class-D Power Amplifier” 2010-IEEE APS, Middle East Conference on Antennas and Propagation (MECAP), Cairo, Egypt, 20 Oct. 2010; Mehdi Sarkeshi, et al., “A Novel Doherty Amplifier for Enhanced Load Modulation and Higher Bandwidth” Microwave Symposium Digest, pp. 763-766, 2008 IEEE MTT-S International; and J. Qureshi, et al., “A Highly Efficient Chireix Amplifier Using Adaptive Power Combining” Microwave Symposium Digest, pp. 759-762, 2008 IEEE MTT-S International.

### SUMMARY

According to one aspect of the embodiments, a power amplifier includes: an amplifier; a matching circuit, including a variable reactance magnetic device having a reactance which varies in accordance with a magnetic field, configured to match an output of the amplifier with a certain impedance; an amplitude detector configured to detect the amplitude of an input signal for the amplifier; and a magnetic-field control circuit configured to apply a magnetic field corresponding to the amplitude detected by the amplitude detector to the variable reactance magnetic device.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an example of a power amplifier according to an embodiment;

FIG. 2 is a graph illustrating an example of characteristics of a variable reactance magnetic device;

FIG. 3 is a graph illustrating an example of a detection of the amplitude of an input signal;

FIG. 4A and FIG. 4B illustrate an example of an operation of the power amplifier;

FIG. 5 illustrates an example of a power amplifier;

FIG. 6 illustrates an example of a variable reactance magnetic device and a coil;

FIG. 7 illustrates another example of a power amplifier;

FIG. 8 illustrates another example of a power amplifier;

FIG. 9 illustrates another example of a power amplifier;

FIG. 10A and FIG. 10B illustrate another example of a power amplifier;

FIG. 11 illustrates another example of a power amplifier; and

FIG. 12 illustrates another example of a power amplifier.

### DESCRIPTION OF EMBODIMENTS

The amplitudes of a transmission signal in a wireless base station may possibly not be constant. The efficiency of a power amplifier depend on the amplitude of the signal. In a power amplifier, the load impedance at which maximum output power is achieved differs from the load impedance at which maximum efficiency is achieved. Accordingly, for example, the power amplifier controls the load impedance in accordance with the signal amplitude in order to alleviate the decrease in average power efficiency. A variable impedance element may include, for example, a variable capacitance element, such as a varactor diode. The variable impedance element may include, for example, a circuit that selects a desired capacitance element from multiple capacitance elements with a switch.

It may be difficult to greatly vary the load impedance of the power amplifier in the variable capacitance element such as the varactor diode. In a typical complicated circuit that uses a variable capacitance element to greatly vary the load impedance of the power amplifier, loss in the power amplifier may become large. A configuration in which a desired capacitance element is selected from multiple capacitance elements by using a switch may not have characteristics that include a high breakdown voltage, high power, high-speed switching, and low loss (low on-resistance).

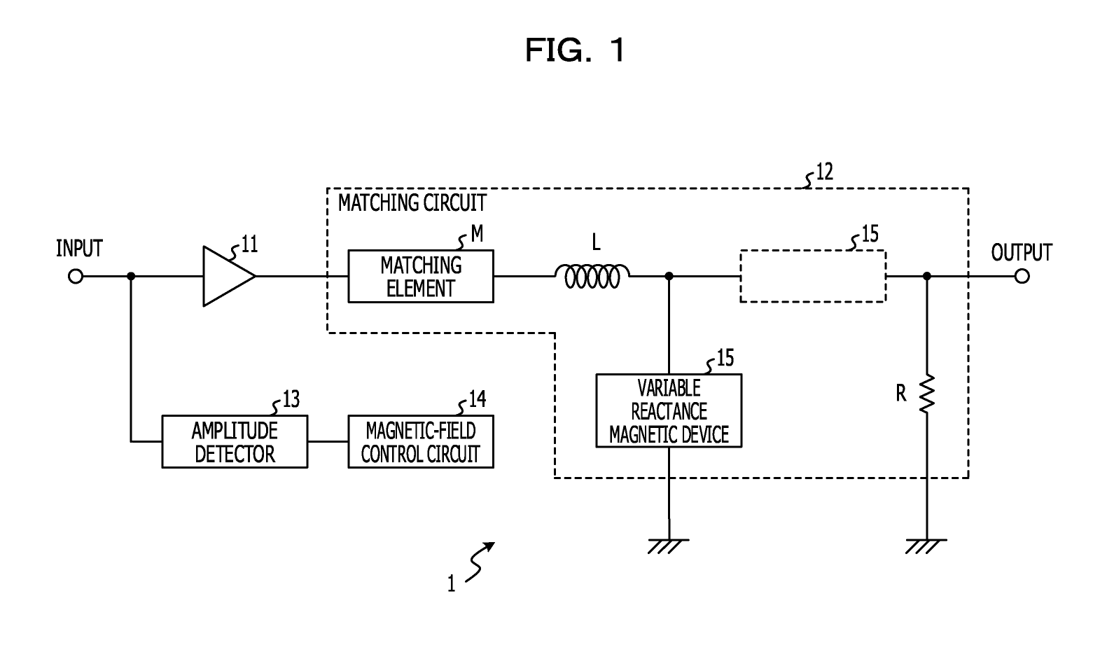

FIG. 1 illustrates an example of a power amplifier. A power amplifier 1 illustrated in FIG. 1 includes an amplifier 11, a matching circuit 12, an amplitude detector 13, and a magnetic-field control circuit 14.

The power amplifier 1 may be used in, for example, a transmitter that transmits a transmission signal. For example, the power amplifier 1 may be used in a base station of a wireless communication system. In this case, the power amplifier 1 amplifies a downlink signal transmitted from the base station to each mobile station. It is assumed in the following description that the power amplifier 1 is used in the base station of a wireless communication system. However, the power amplifier may be used for other applications, instead of the wireless communication system.

The downlink signal is input into the power amplifier 1. The downlink signal may be a radio-frequency modulation signal. For example, the downlink signal may be a modulation signal within an 800-MHz frequency band or a 1-GHz frequency band. The amplitude of the downlink signal may not be constant. For example, the amplitude of the downlink signal varies with the modulation method. The modulation method may be dynamically varied in accordance with the bit rate of data transmitted via the downlink signal.

The amplifier 11 amplifies an input signal. For example, the amplifier 11 amplifies the downlink signal. At this point, the amplifier 11 operates in, for example, an automatic gain control (AGC) mode in which the input signal is amplified with specified gain. The amplifier 11 may operate in an automatic level control (ALC) mode in which a specified output level is kept.

The matching circuit 12 is provided between the amplifier 11 and an output port and performs impedance matching to match the output from the amplifier 11 with a certain impedance. For example, a 50-Ω antenna is electrically coupled to the output port of the power amplifier 1. The matching circuit 12 may be designed so that the output impedance of the amplifier 11 is matched with 50Ω.

The matching circuit 12 includes a matching element M, an inductor L, a resistor R, and a variable reactance magnetic device 15. The matching element M may include, for example, a stub. The length of the stub may be designed in accordance with the certain impedance. The matching element, the inductance component, and the resistance component exist in the matching circuit 12 illustrated in FIG. 1. Accordingly, the inductance component and/or the resistance component may be included in a conducting line via which a signal is propagated from the amplifier 11 to the output port.

The variable reactance magnetic device 15 may be used as a circuit element that provides desired reactance. The reactance of the variable reactance magnetic device 15 varies in accordance with an applied magnetic field.

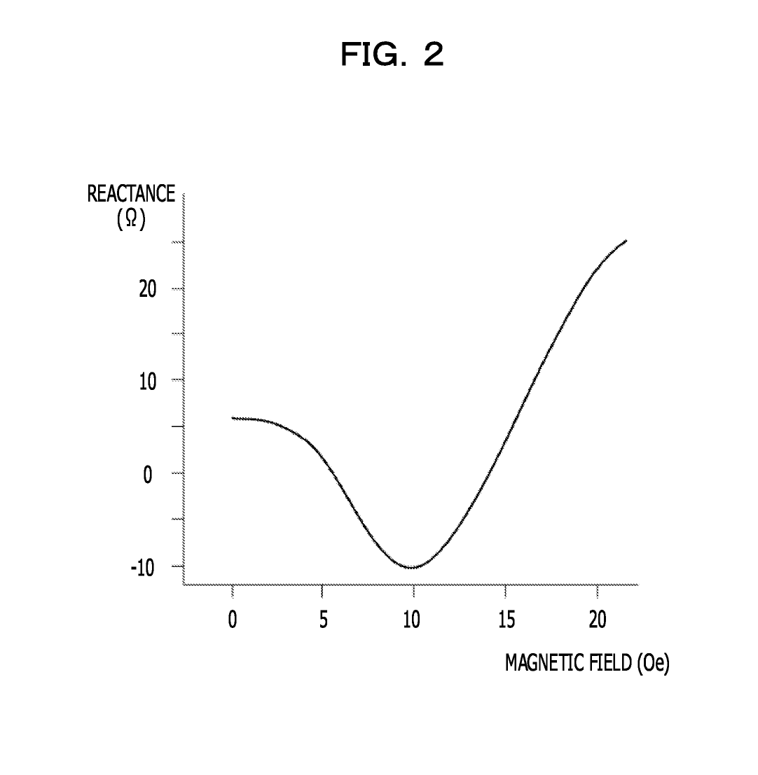

FIG. 2 illustrates an example of characteristics of a variable reactance magnetic device. The reactance of the variable reactance magnetic device 15, which is measured for a radio frequency (1 GHz here), is illustrated in FIG. 2. For example, high-frequency current flows through the variable reactance magnetic device 15 when measuring the reactance. In FIG. 2, the horizontal axis represents the magnetic field applied to the variable reactance magnetic device 15. The direction of the magnetic field may be parallel or substantially parallel to the direction in which the high-frequency current flows through the variable reactance magnetic device 15. The vertical axis represents the reactance of the variable reactance magnetic device 15.

In the graph illustrated in FIG. 2, the reactance varies, starting from about 5 [Ω] and reaching about −10 [Ω], when the magnetic field applied to the variable reactance magnetic device 15 is increased from 5 [Oe] to 10 [Oe]. In an area where the magnetic field is higher than 10 [Oe], the reactance varies, starting from a negative value and proceeding to a positive value. For example, a radio-frequency reactance element described in Japanese Laid-open Patent Publication No. 2004-327755 may be used.

The variable reactance magnetic device 15 may be mounted at the position in the matching circuit 12 illustrated in FIG. 1 or may be mounted at another position in the matching circuit 12. For example, the variable reactance magnetic device 15 may be mounted at a position represented by a broken line in the matching circuit 12 illustrated in FIG. 1. For example, the variable reactance magnetic device 15 may be coupled in parallel to a load or may be coupled in series to the load.

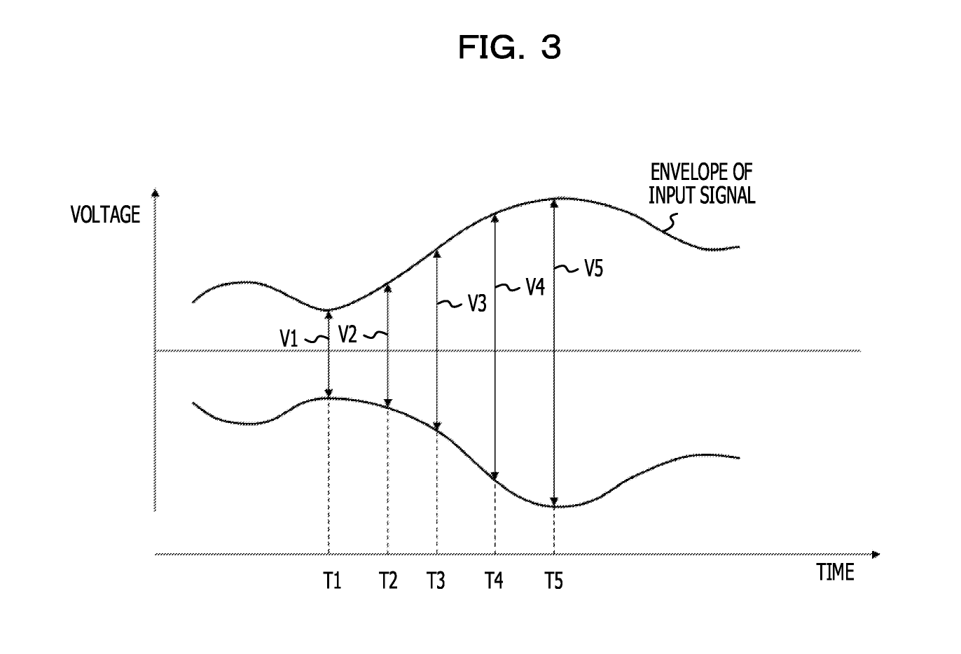

FIG. 3 illustrates an example of a detection of the amplitude of the input signal. The amplitude detector 13 detects the amplitude of the input signal of the power amplifier 1. The amplitude detector 13 may include, for example, an envelope detector circuit. The amplitude detector 13 outputs a voltage signal representing the envelope of the input signal, as illustrated in FIG. 3. The voltage signal representing the envelope of the input signal may correspond to the amplitude of the input signal. A known technology may be used as the envelope detector circuit.

The magnetic-field control circuit 14 applies a magnetic field having a strength corresponding to the amplitude of the input signal detected by the amplitude detector 13 to the variable reactance magnetic device 15. The magnetic-field control circuit 14 is mounted so that the direction of the high-frequency current flowing through the variable reactance magnetic device 15 is parallel or substantially parallel to the direction of the magnetic field. The magnetic-field control circuit 14 generates the magnetic field corresponding to the amplitude of the input signal so as to increase the efficiency of the power amplifier 1 and applies the generated magnetic field to the variable reactance magnetic device 15. The drain efficiency of the power amplifier 1 may be represented by Efficiency=Pₒᵤₜ/VI, where Pₒᵤₜ denotes the power of an output signal from the power amplifier 1, V denotes the voltage supplied to the power amplifier 1, and I denotes the current supplied to the power amplifier 1.

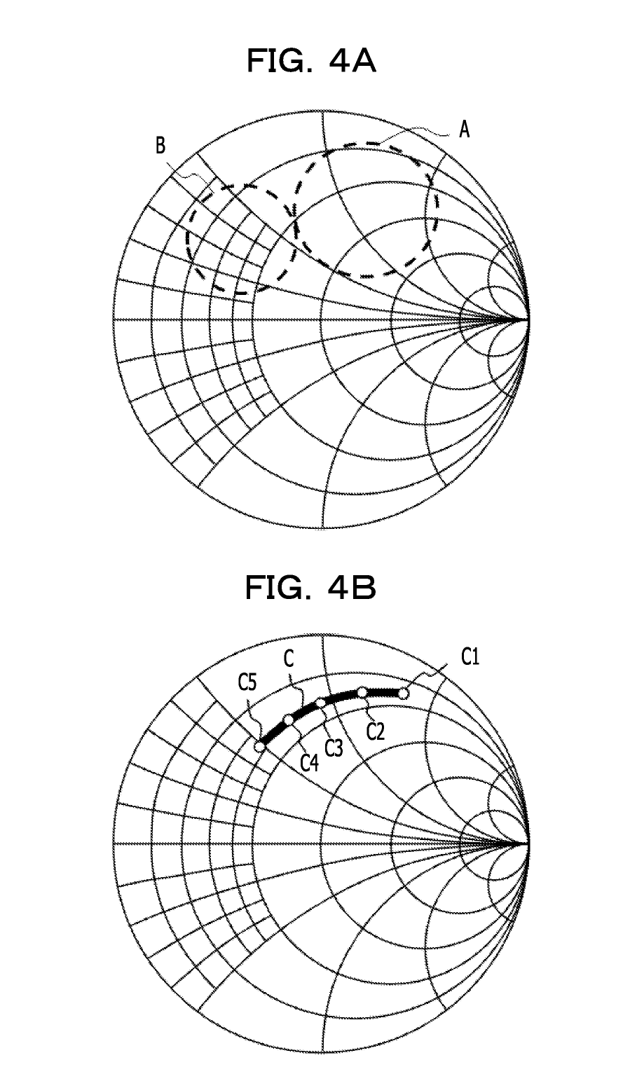

FIG. 4A and FIG. 4B illustrate an example of an operation of a power amplifier. In a Smith chart illustrated in FIG. 4A, an area A represented by a broken line indicates an impedance area where the efficiency of the power amplifier 1 is high. In order to increase the efficiency of the power amplifier 1, the matching circuit 12 may be designed so as to have a maximum impedance point in efficiency within the area A.

The envelope of a radio-frequency (RF) transmission signal greatly varies with time and the difference between the average power and the instantaneous maximum power is very large. Accordingly, in order to linearly operate the amplifier in any state, the instantaneous maximum power is linearly amplified, whereas the power efficiency is maximized at the average power lower than the output level. For example, in FIG. 4A, when the output power decreases from the power at the maximum impedance point in power in an area B represented by a broken line to the average power, the load impedance point may be controlled so as the efficiency does not decrease at any power.

The power amplifier 1 dynamically controls the impedance of the matching circuit 12 in accordance with the output power so as to meet the above conditions. For example, the power amplifier 1 controls the matching circuit 12 so that the impedance of the matching circuit 12 draws a curve C illustrated in FIG. 4B for the output power corresponding to the variation in amplitude of the input signal. The impedance of the matching circuit 12 may vary in a direction from C1 to C5 as the amplitude of the input signal increases. The curve C may be achieved, for example, by varying a certain reactance (an imaginary component of the impedance) corresponding to the load.

The relationship between the output power corresponding to the amplitude of the input signal and the impedance of the matching circuit 12 may be acquired in advance for the curve C. The relationship may be acquired by, for example, measurement or simulation. The curve C is achieved by varying the reactance of the matching circuit 12 so that the curve C constantly moves through high-efficiency points for the output power. The magnetic field applied to the variable reactance magnetic device 15 may be controlled to achieve the variation in reactance.

Magnetic field data for achieving the curve C is prepared for the amplitude of the input signal in the power amplifier 1. The power amplifier 1 generates the magnetic field corresponding to the amplitude of the input signal and then applies the generated magnetic field to the variable reactance magnetic device 15. The power amplifier 1 amplifies the signal by using the output impedance represented by the curve C.

For example, magnetic fields of 7 [Oe] to 10 [Oe] may be associated with amplitudes V1 to V5 illustrated in FIG. 3. The amplitudes V1 to V5 may correspond to the voltages of the envelopes supplied by the amplitude detector 13. In FIG. 2, when the magnetic field applied to the variable reactance magnetic device 15 is varied from 7 [Oe] to 10 [Oe], the reactance of the variable reactance magnetic device 15 may be between −5 [Ω] to −10 [Ω]. When the reactance of the variable reactance magnetic device 15 is between −5 [Ω] to −10 [Ω], the impedance of the matching circuit 12 may be between C1 to C5.

At a time T1, the amplitude V1 is detected by the amplitude detector 13. The magnetic-field control circuit 14 generates a magnetic field of 7 [Oe] corresponding to the amplitude V1. The reactance of the variable reactance magnetic device 15 may be equal to −5 [Ω] and the impedance of the matching circuit 12 is controlled so as to have a value of C1. For example, the power amplifier 1 amplifies the signal by using the output impedance C1. Accordingly, the power amplifier 1 amplifies the signal with high efficiency.

At a time T5, the amplitude V5 is detected by the amplitude detector 13. The magnetic-field control circuit 14 generates a magnetic field of 10 [Oe] corresponding to the amplitude V5. The reactance of the variable reactance magnetic device 15 is equal to −10 [Ω] and the impedance of the matching circuit 12 is controlled so as to have a value of C5. For example, the power amplifier 1 amplifies the signal by using the output impedance C5. Accordingly, the power amplifier 1 controls the matching circuit 12 so as to have an impedance point where the high-efficiency operation is achieved as at the impedance C1.

Similarly, at times T2, T3, and T4, magnetic fields corresponding to the amplitudes V2, V3, and V4, respectively, are generated. Accordingly, the power amplifier 1 amplifies the signal by using the output impedances C2, C3, and C4 at the times T2, T3, and T4, respectively.

The power amplifier 1 dynamically controls the output impedance by using the variable reactance magnetic device 15. For example, the magnetic-field control circuit 14 generates a magnetic field corresponding to the amplitude of the input signal so that the impedance of the matching circuit 12 fulfills the impedance characteristic (the curve C in FIG. 4B) specified in advance for the amplitude of the input signal and then applies the generated magnetic field to the variable reactance magnetic device 15. The reactance of the variable reactance magnetic device 15 may easily vary greatly, compared with the variable capacitance element such as the varactor diode. Because the matching circuit 12 is controlled so as to have a desired impedance, the power amplifier 1 may operate with high efficiency.

It may be difficult for the matching circuit 12 to have a desired output impedance if the variable amount of reactance of the matching circuit 12 is small. In this case, the power amplifier may not operate with high efficiency before the power amplifier reaches a wide range back-off point (from high output power to low output power).

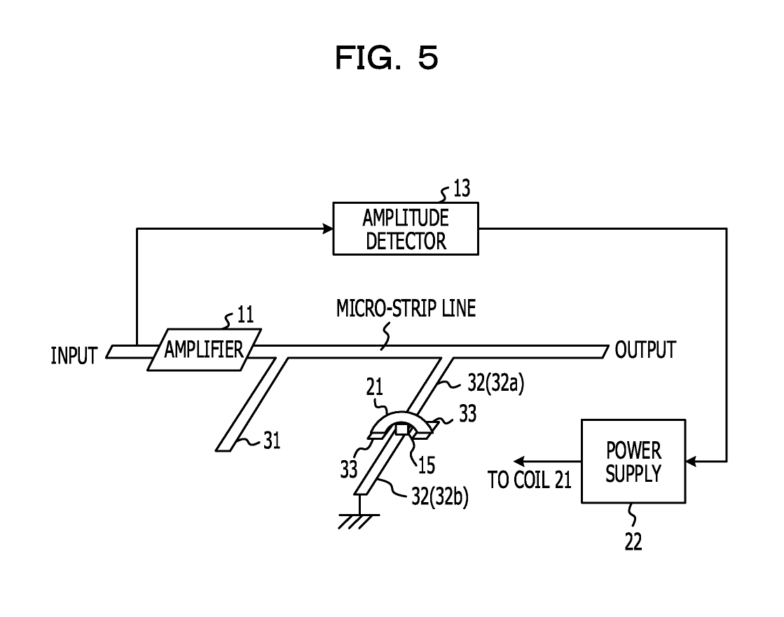

FIG. 5 illustrates an example of a power amplifier. The power amplifier 1 illustrated in FIG. 5 includes a coil 21 and a power supply 22 that supplies current to the coil as the magnetic-field control circuit 14 illustrated in FIG. 1.

The matching circuit 12 includes the variable reactance magnetic device 15 and a micro-strip line formed on a substrate. The micro-strip line may be formed of, for example, a copper material. The inductor L and the resistor R illustrated in FIG. 1 may include, for example, the micro-strip line. In addition to the micro-strip line, an inductance element and/or a resistance element may be mounted on the substrate. The matching element M illustrated in FIG. 1 may include, for example, a stub formed from the micro-strip line. In the example in FIG. 5, stubs 31 and 32 are formed on the substrate.

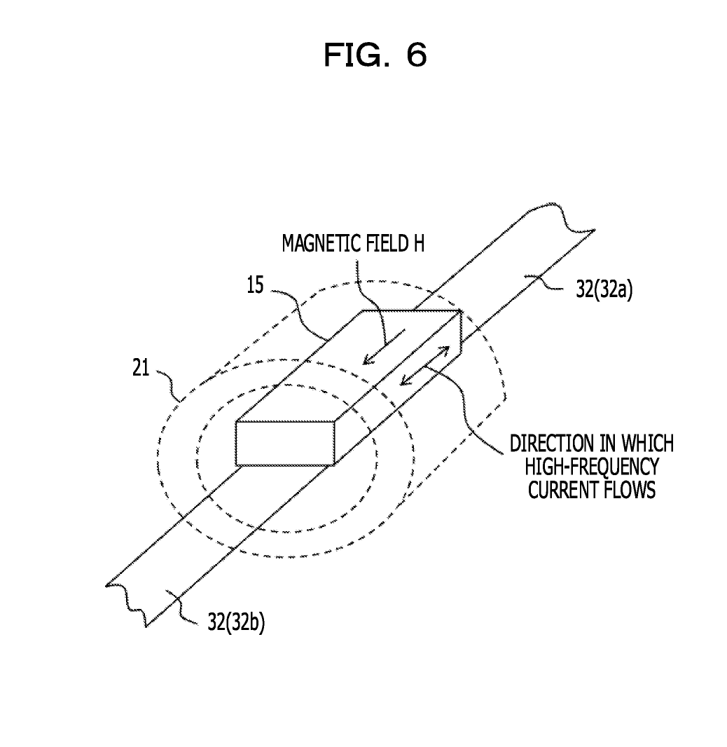

FIG. 6 illustrates an example of a variable reactance magnetic device and the coil. The variable reactance magnetic device 15 may be mounted on an intermediate portion of the stub 32, as illustrated in FIG. 6. The stub 32 includes stub elements 32a and 32b that are electrically coupled to each other. The variable reactance magnetic device 15 is mounted between the stub elements 32a and 32b. For example, one end of the variable reactance magnetic device 15 is electrically coupled to the stub element 32a and the other end of the variable reactance magnetic device 15 is electrically coupled to the stub element 32b. A leading end of the stub 32 on which the variable reactance magnetic device 15 is mounted is, for example, grounded in the example in FIG. 5.

The coil 21 is arranged so as to surround the variable reactance magnetic device 15 in the manner illustrated in FIG. 6. The coil 21 is arranged so as to surround the variable reactance magnetic device 15 by using holes 33 formed in the substrate in the manner illustrated in FIG. 5. A pair of holes 33 may be formed near the variable reactance magnetic device 15.

The power supply 22 supplies the current corresponding to the amplitude of the input signal detected by the amplitude detector 13 to the coil 21. A magnetic field corresponding to the amplitude of the input signal is generated by the coil 21. The method of generating the magnetic field corresponding to the amplitude of the input signal is described above with reference to FIG. 2 to FIG. 4B. Both ends of a winding of the coil 21 may be coupled to the power supply 22.

The amplifier 11 amplifies the radio-frequency signal. The frequency of the radio-frequency signal may be around 800 MHz to 1 GHz. The radio-frequency signal amplified by the amplifier 11 is also led to the variable reactance magnetic device 15 when the radio-frequency signal is propagated to the output port of the power amplifier 1 via the micro-strip line. Accordingly, when the amplifier 11 is amplifying the radio-frequency signal, a high-frequency current flows through the variable reactance magnetic device 15 in the manner illustrated in FIG. 6.

Because the power supply 22 supplies the current corresponding to the amplitude of the input signal of the power amplifier 1 to the coil 21, a magnetic field H illustrated in FIG. 6 is generated. The direction of the magnetic field H is parallel or substantially parallel to the direction of the high-frequency current flowing through the variable reactance magnetic device 15. The permeability of the variable reactance magnetic device 15 varies in a direction orthogonal to the current direction. Accordingly, the reactance of the variable reactance magnetic device 15 greatly varies with respect to the high-frequency current. The relationship between the strength of the magnetic field applied to the variable reactance magnetic device 15 and the reactance of the variable reactance magnetic device 15 may be as illustrated in, for example, FIG. 2.

The variable reactance magnetic device 15 may have a width of, for example, about 50 μm. The coil 21 may be, for example, a 15β-turn air core coil. The coil 21 may have an opening having a diameter of, for example, about 4 mm. For example, a current of 10 mA to 15 mA flows through the coil 21 to generate a magnetic field of 5 [Oe] to 7 [Oe].

The stub 32 on which the variable reactance magnetic device 15 is mounted may be designed so as to have a length of, for example, λ/4. λ represents the wavelength of the radio-frequency signal amplified by the amplifier 11. For example, the leading end of the stub 32 is grounded. At the leading end of the stub 32, the amplitude of the current of the radio-frequency signal may be essentially zero. The amplitude of the current of the radio-frequency signal increases near a midpoint of the stub 32. Accordingly, when the variable reactance magnetic device 15 is mounted near the midpoint of the stub 32, the reactance may greatly vary with respect to the variation in the applied magnetic field. Consequently, the variable reactance magnetic device 15 may be mounted near the midpoint of the stub 32. The “mounting of the variable reactance magnetic device 15 near the midpoint of the stub 32” may mean that the length of the stub element 32a is substantially equal to the length of the stub element 32b.

In the matching circuit 12, the coil 21 is mounted so as to surround the variable reactance magnetic device 15. Because the current flowing through the coil 21 is controlled in accordance with the amplitude of the input signal, the reactance of the variable reactance magnetic device 15 is controlled. Because the matching circuit 12 supplies desired output impedance in accordance with the amplitude of the input signal, the power amplifier 1 may amplify the signal with high efficiency even when the amplitude of the input signal varies.

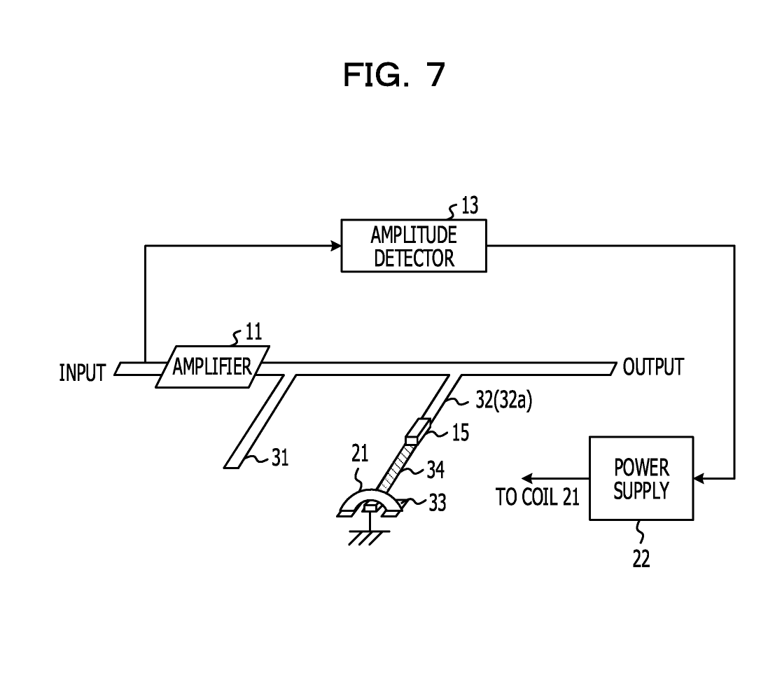

FIG. 7 illustrates another example of a power amplifier. Referring to FIG. 7, the stub 32 on which the variable reactance magnetic device 15 is mounted includes the stub elements 32a and 32b. A magnetic metal film 34 may be formed on the surface of the stub element 32b. The magnetic metal film 34 is represented by a hatched area in FIG. 7. The stub element 32b may be formed on the bottom side of the magnetic metal film 34.

The coil 21 may be mounted at the leading end of the stub 32, for example, at the leading end of the magnetic metal film 34. The leading end of the stub 32 is grounded. For example, at a position to which the magnetic field is applied from the coil 21, the amplitude of the current of the radio-frequency signal is small and may be substantially zero. The effect of a standing wave may be reduced in the power amplifier illustrated in FIG. 7. The power supply 22 may be connected to both ends of the wiring of the coil 21.

The magnetic metal film 34 is magnetically coupled to the variable reactance magnetic device 15. The coil 21 may be mounted so as to surround the magnetic metal film 34, for example, the leading end portion of the magnetic metal film 34. Accordingly, the magnetic field generated by the current that flows through the coil 21 is applied to the variable reactance magnetic device 15 via the magnetic metal film 34.

The magnetic metal film 34 may be formed of a soft magnetic material. The magnetic metal may be, for example, CoCrPt or CoFeB.

The amplitude detector 13 and the power supply 22 may be substantially the same in the examples in FIG. 5 and FIG. 7. Accordingly, the impedance of the matching circuit 12 may be controlled also in the power amplifier illustrated in FIG. 7 to cause the power amplifier 1 to amplify the signal with high efficiency.

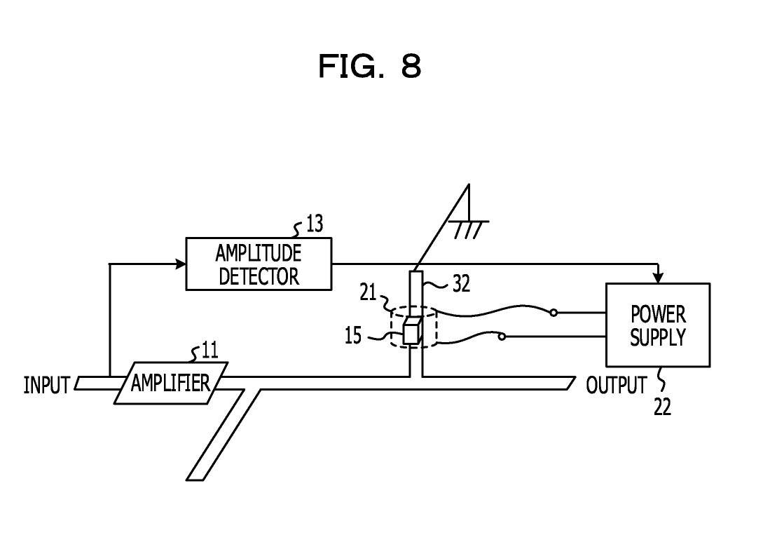

FIG. 8 illustrates another example of a power amplifier. Referring to FIG. 8, the stub 32 on which the variable reactance magnetic device 15 is mounted is formed so as to extend in the vertical direction with respect to the substrate on which the amplifier 11 and the like are mounted. An auxiliary substrate may be vertically fixed to a main substrate on which the amplifier 11 and the like are mounted. The stub 32 is formed by using the micro-strip line on the auxiliary substrate. The stub 32 is electrically coupled to the micro-strip line via which the signal is propagated from the amplifier 11 to the output port.

The variable reactance magnetic device 15 may be mounted on an intermediate portion of the stub 32, as in the examples in FIG. 5 and FIG. 7. The coil 21 is arranged so as to surround the variable reactance magnetic device 15. The coil 21 is represented by a broken line in FIG. 8.

The amplitude detector 13 and the power supply 22 may be substantially the same as in FIG. 5, FIG. 7, and FIG. 8. Accordingly, the impedance of the matching circuit 12 may be controlled in accordance with the amplitude of the input signal to cause the power amplifier 1 to amplify the signal with high efficiency. Holes for mounting the coil 21 may not be formed in the main substrate on which the power amplifier 11 and the like are mounted.

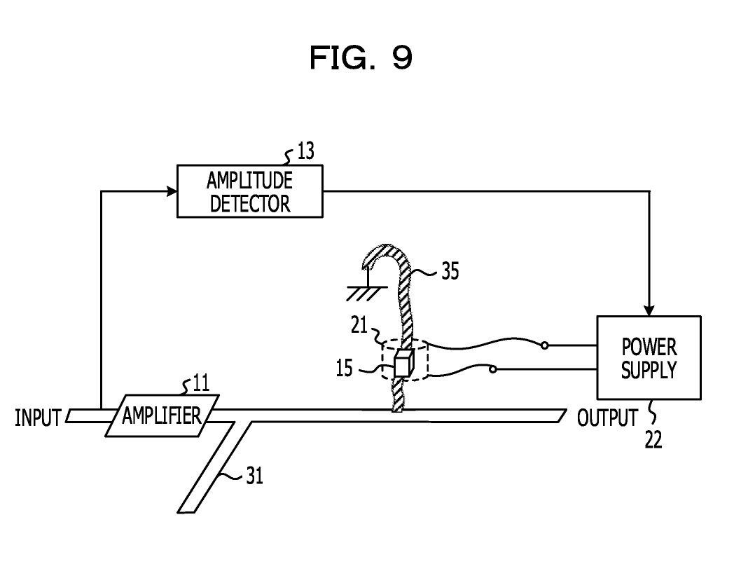

FIG. 9 illustrates another example of a power amplifier. The power amplifier 1 illustrated in FIG. 9 includes a coaxial cable 35 instead of the stub 32 illustrated in FIG. 5, FIG. 7, and FIG. 8. The impedance of the coaxial cable 35 may be determined in accordance with a load. For example, when a 50-Ω antenna is coupled to the output of the power amplifier 1, the impedance of the coaxial cable 35 may be equal to 50 [Ω]. The coaxial cable 35 is electrically coupled to the micro-strip line via which the signal is propagated from the amplifier 11 to the output port.

The variable reactance magnetic device 15 may be provided on an intermediate portion of the coaxial cable 35. The coil 21 may be arranged so as to surround the variable reactance magnetic device 15. The coil 21 is represented by a broken line in FIG. 9.

The amplitude detector 13 and the power supply 22 may be substantially the same as in FIG. 5, FIG. 7, FIG. 8, and FIG. 9. Accordingly, the impedance of the matching circuit 12 may also be controlled in accordance with the amplitude of the input signal in the power amplifier illustrated in FIG. 9 to cause the power amplifier 1 to amplify the signal with high efficiency. Because the coil 21 is arranged at a desired position, the degree of freedom of the arrangement of the coil 21 may be increased.

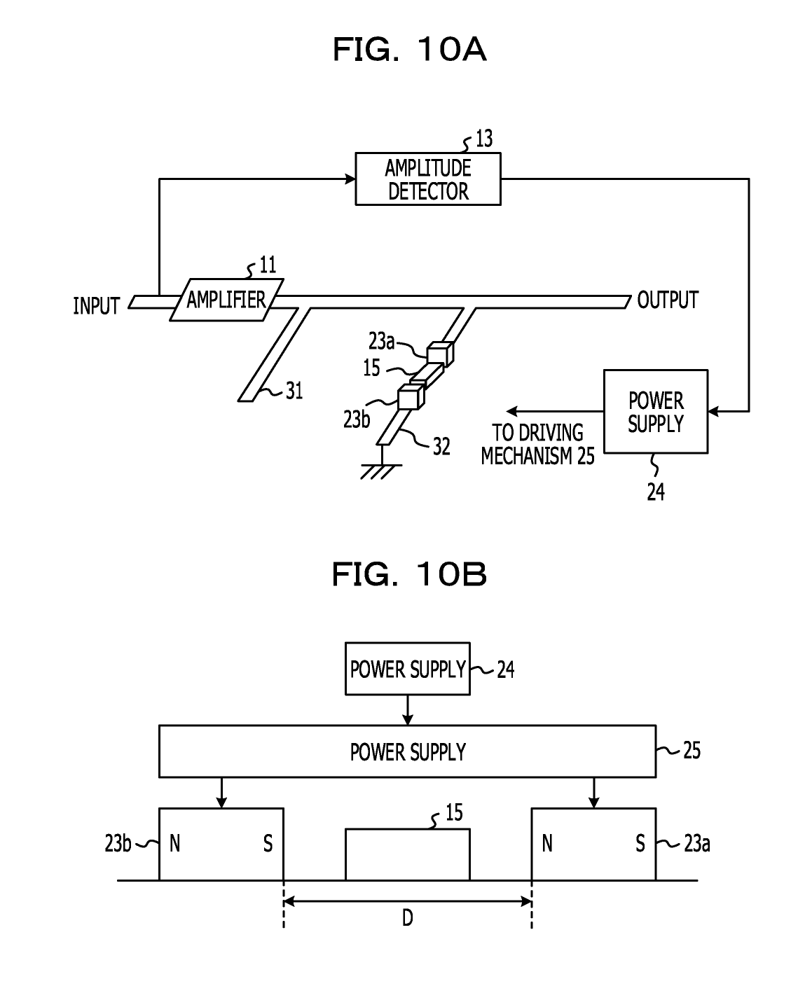

FIG. 10A and FIG. 10B illustrate another example of a power amplifier. The magnetic-field control circuit 14 illustrated in FIG. 1 includes a pair of permanent magnets 23a and 23b illustrated in FIG. 10A.

The pair of permanent magnets 23a and 23b are arranged so as to sandwich the variable reactance magnetic device 15 in a manner as illustrated in FIG. 10B. For example, the variable reactance magnetic device 15 is arranged between the pair of permanent magnets 23a and 23b. At least one of the permanent magnets 23a and 23b may be movably mounted in the direction parallel to the stub 32.

The north pole of one of the permanent magnets 23a and 23b, for example, the north pole of the permanent magnet 23a is directed towards the variable reactance magnetic device 15 and the south pole of the other of the permanent magnets 23a and 23b, for example, the south pole of the permanent magnet 23b is directed towards the variable reactance magnetic device 15. Accordingly, a magnetic field, the direction of which is parallel or substantially parallel to the direction of the high-frequency current flowing through the variable reactance magnetic device 15, is generated by the permanent magnets 23a and 23b.

A power supply 24 generates voltage corresponding to the amplitude of the input signal. A driving mechanism 25 controls a distance D between the permanent magnets 23a and 23b in accordance with the voltage generated by the power supply 24. For example, the driving mechanism 25 controls the distance between the variable reactance magnetic device 15 and the permanent magnet 23a and the distance between the variable reactance magnetic device 15 and the permanent magnet 23b in accordance with the amplitude detected by the amplitude detector 13. The magnetic field applied to the variable reactance magnetic device 15 weakens when the distance D is short and the magnetic field applied to the variable reactance magnetic device 15 strengthens when the distance D is long. Accordingly, in the power amplifier illustrated in FIG. 10A and FIG. 10B, the reactance corresponding to the amplitude of the input signal is generated, as in the examples in FIG. 5, FIG. 7, FIG. 8, and FIG. 9.

The driving mechanism 25 may move at least one of the permanent magnets 23a and 23b in a direction parallel to that of the stub 32. The driving mechanism 25 may include, for example, a spring or a piezoelectric element. For example, when the driving mechanism 25 includes a piezoelectric element, the distance D is controlled in accordance with the voltage supplied from the power supply 24.

The impedance of the matching circuit 12 may be controlled in accordance with the amplitude detected by the amplitude detector 13 in substantially the same manner as in FIG. 5, FIG. 7, FIG. 8, FIG. 9, and FIG. 10A and FIG. 10B. Accordingly, the power amplifier 1 may amplify the signal with high efficiency.

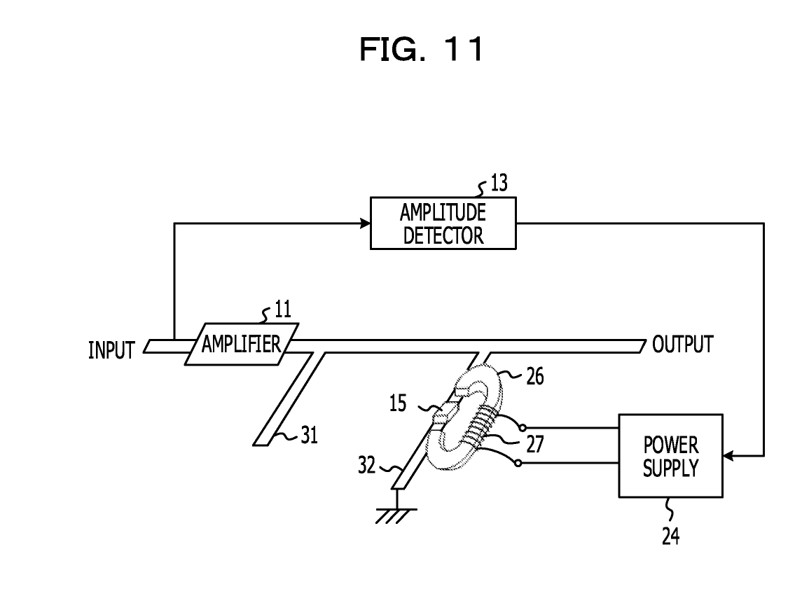

FIG. 11 illustrates another example of a power amplifier. Referring to FIG. 11, the magnetic-field control circuit 14 in the power amplifier 1 includes the power supply 22, a yoke 26, and a coil 27.

The yoke 26 and the coil 27 operate as a magnetic circuit when current is supplied from the power supply 22 to the yoke 26 and the coil 27. The yoke 26 includes a gap, as illustrated in FIG. 11. The coil 27 is wound around the yoke 26.

The yoke 26 is arranged so that the variable reactance magnetic device 15 is positioned in the gap of the yoke 26. Accordingly, the magnetic field the direction of which is parallel or substantially parallel to the direction of the high-frequency current flowing through the variable reactance magnetic device 15 is generated upon supply of the current from the power supply 22 to the coil 27. Accordingly, the power supply 22 supplies a current corresponding to the amplitude of the input signal to the coil 27. Also in the power amplifier illustrated in FIG. 11, the reactance corresponding to the amplitude of the input signal may be generated, as in FIG. 5 and FIG. 7 to FIG. 10B.

For example, the material of the yoke 26 may be iron. The core radius of the yoke 26 may be 5 mm and the gap of the yoke 26 may have a length of 1.5 mm. The number of windings of the coil 27 may be 50. When current of 8 mA to 18 mA flows through the coil 27, a magnetic field of 3 [Oe] to 7.5 [Oe] is generated.

The impedance of the matching circuit 12 may be controlled in accordance with the amplitude detected by the amplitude detector 13 in substantially the same manner as in FIG. 5 and FIG. 7 to FIG. 11. The power amplifier 1 illustrated in FIG. 11 may amplify the signal with high efficiency.

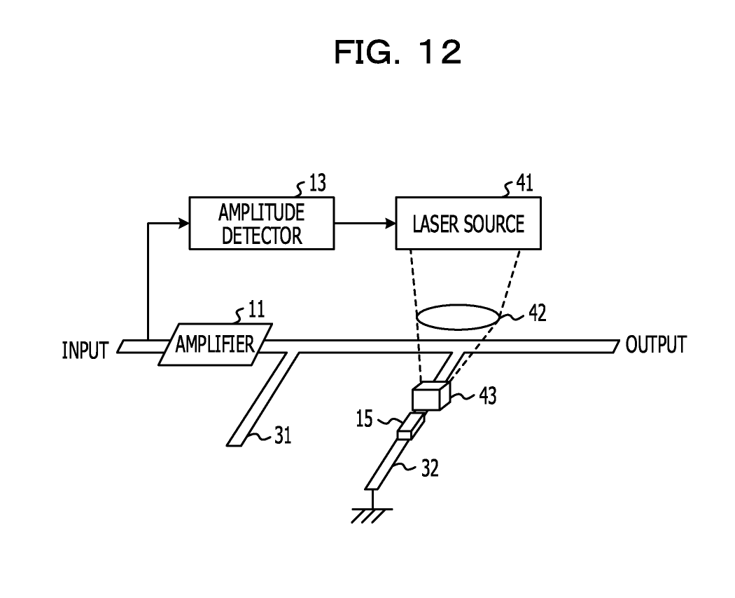

FIG. 12 illustrates another example of a power amplifier. Referring to FIG. 12, the magnetic-field control circuit 14 in the power amplifier 1 includes a laser source 41, a lens 42, and a magnetic substance 43.

The laser source 41 generates laser light with power corresponding to the amplitude of the input signal. The laser light may have an arbitrary wavelength. The lens 42 directs the laser light generated by the laser source 41 to the magnetic substance 43.

The magnetic substance 43 is arranged near the variable reactance magnetic device 15 so that a magnetic field, the direction of which is parallel or substantially parallel to the direction of the high-frequency current flowing through the variable reactance magnetic device 15, is generated. In the magnetic substance 43, the magnitude of the magnetization varies with temperature. The temperature of the magnetic substance 43 is controlled by the laser light generated by the laser source 41. For example, the temperature of the magnetic substance 43 is low when the laser light has low power and the temperature of the magnetic substance 43 is high when the laser light has high power. The generation of laser light having power corresponding to the amplitude of the input signal causes a magnetic field corresponding to the amplitude of the input signal to be generated. For example, the reactance of the variable reactance magnetic device 15 is controlled in accordance with the amplitude of the input signal. The magnetic substance 43 may include, for example, GdFeCo or GdTbFeCo.

The power amplifier 1 illustrated in FIG. 12 may amplify the signal with high efficiency, as in FIG. 5 and FIG. 7 to FIG. 11.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A power amplifier comprising:
an amplifier;
a matching circuit, including a variable reactance magnetic device having a reactance which varies in accordance with a magnetic field, configured to match an output of the amplifier with a certain impedance;
an amplitude detector configured to detect the amplitude of an input signal for the amplifier; and
a magnetic-field control circuit configured to apply a magnetic field corresponding to the amplitude detected by the amplitude detector to the variable reactance magnetic device.

2. The power amplifier according to claim 1,
wherein the magnetic-field control circuit generates the magnetic field so that the impedance of the matching circuit meets certain impedance characteristics for the amplitude of the output signal of the amplifier to apply the generated magnetic field to the variable reactance magnetic device.

3. The power amplifier according to claim 1,
wherein the magnetic-field control circuit generates the magnetic field parallel or substantially parallel to the direction of high-frequency current flowing through the variable reactance magnetic device.

4. The power amplifier according to claim 1,
wherein the magnetic-field control circuit includes:
a coil; and
a power supply configured to supply current corresponding to the amplitude detected by the amplitude detector to the coil.

5. The power amplifier according to claim 4,
wherein the coil is arranged so as to surround the variable reactance magnetic device.

6. The power amplifier according to claim 4;
wherein the magnetic-field control circuit further includes a magnetic metal magnetically coupled to the variable reactance magnetic device, and
wherein the coil is arranged so as to surround the magnetic metal.

7. The power amplifier according to claim 4,
wherein the matching circuit includes a stub formed so as to extend in a direction vertical or substantially vertical to a substrate on which the amplifier is mounted, and
wherein the variable reactance magnetic device is mounted on an intermediate portion of the stub.

8. The power amplifier according to claim 4,
wherein the matching circuit includes a stub formed by using a coaxial cable, and
wherein the variable reactance magnetic device is mounted on an intermediate portion of the coaxial cable.

9. The power amplifier according to claim 3,
wherein the magnetic-field control circuit includes:
a permanent magnet; and
a driving mechanism configured to control a distance between the variable reactance magnetic device and the permanent magnet in accordance with the amplitude detected by the amplitude detector.

10. The power amplifier according to claim 1,
wherein the magnetic-field control circuit includes:
a magnetic circuit having a gap;
a power supply configured to supply current corresponding to the amplitude detected by the amplitude detector to the magnetic circuit,
wherein the variable reactance magnetic device is arranged in the gap of the magnetic circuit.

11. The power amplifier according to claim 10,
wherein the magnetic circuit includes:
a yoke including the gap; and
a coil wound around the yoke,
wherein the power supply supplies current corresponding to the amplitude detected by the amplitude detector to the coil.

12. The power amplifier according to claim 1,
wherein the magnetic-field control circuit includes:
a magnetic substance arranged near the variable reactance magnetic device, the magnitude of magnetization of the magnetic substance varying with temperature; and
a light source configured to illuminate the magnetic material with light of power corresponding to the amplitude detected by the amplitude detector.
